(19) United States
(12) Patent Application Publication
(10) Pub. No.: US 2025/0143065 A1
(43) Pub. Date: May 1, 2025

(54) DISPLAY APPARATUS HAVING A LIGHT-EMITTING DEVICE

(71) Applicant: LG Display Co., Ltd., Seoul (KR)

(72) Inventors: Yu Jeong LEE, Paju-si (KR); Chun Ki KIM, Paju-si (KR)

(73) Assignee: LG Display Co., Ltd., Seoul (KR)

(21) Appl. No.: 18/882,158

(22) Filed: Sep. 11, 2024

(30) Foreign Application Priority Data
Oct. 26, 2023 (KR) 10-2023-0144842

(51) Int. Cl. H10K 50/12; H10K 50/19; H10K 101/40; H10K 102/00

(52) U.S. Cl. CPC H10K 50/12; H10K 50/19; H10K 2101/40; H10K 2102/351

(57) ABSTRACT

A display apparatus including a light-emitting device is discussed. The light-emitting device can include a light-emitting unit between an anode electrode and a cathode electrode. The light-emitting unit can include at least one blue emission stack. The blue emission stack can include a first light-emitting layer and a second light-emitting layer contacting a surface of the first light-emitting layer toward the cathode electrode. A host of the second light-emitting layer can have a higher triplet energy level than a host of the first light-emitting layer. Thus, in the display apparatus, deterioration in the efficiency and life-span of the light-emitting device due to the accumulation of triplet excitons can be prevented or minimized. As a result, low power driving is possible, and power consumption is reduced.

### CROSS-REFERENCE TO RELATED APPLICATIONS

This application claims priority to Korean Patent Application No. 10-2023-0144842, filed in the Republic of Korea on Oct. 26, 2023, the entire contents of which is hereby expressly incorporated by reference into the present application.

### BACKGROUND

### Field

The present disclosure relates to a display apparatus with improved efficiency and improved use length in which a light-emitting device is disposed in each pixel area.

### Discussion of the Related Art

Generally, a display apparatus provides an image to a user. For example, the display apparatus can include a plurality of light-emitting devices. Each of the light-emitting devices can emit light for displaying a specific color. For example, each of the light-emitting devices can include a light-emitting layer between a lower electrode and an upper electrode. The light-emitting layer can generate light using energy from the recombination of electrons and holes. For example, the light-emitting layer can include a host and a dopant doped into the host.

A region of the light-emitting layer in which the electrons and the holes recombine can vary depending on the characteristics of the host. For example, when the host has good hole transport properties, a region in which the electrons and the holes recombine can occur close to a surface of the light-emitting layer, which is disposed close to the second electrode that functions as a cathode electrode. For instance, in each light-emitting device of the display apparatus, triplet exciton can be accumulated at a surface of the light-emitting layer.

Thus, in the display apparatus, a layer disposed close to the surface of the light-emitting layer can relatively quickly deteriorate due to the accumulation of triplet excitons. For example, in the display apparatus, an electron transport layer disposed between the light-emitting layer and the second electrode of the light-emitting device can relatively quickly deteriorate. As such, in the display apparatus, the efficiency and life-span (e.g., use length) of each light-emitting device can be reduced or deteriorated.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of improving efficiency and life-span of the light-emitting device.

Another object of the present disclosure is to provide a display apparatus capable of preventing a layer disposed adjacent to a surface of the light-emitting layer from rapidly deteriorating due to accumulation of triplet excitons.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. A first electrode is disposed on a pixel area of the device substrate. An upper emission stack is disposed on the first electrode. The upper emission stack has a stacked structure of a first blue light-emitting layer and a second blue light-emitting layer. An electron transport layer is disposed on the second blue light-emitting layer of the upper emission stack. A second electrode is disposed on the electron transport layer. The second blue light-emitting layer is in contact with a surface of the first blue light-emitting layer toward the electron transport layer. A second host of the second blue light-emitting layer has a higher triplet energy level than a first host of the first blue light-emitting layer.

According to an aspect of the present disclosure, the Lowest Unoccupied Molecular Orbital (LUMO) energy level of the electron transport layer can be higher than the LUMO energy level of the second blue light-emitting layer.

According to an aspect of the present disclosure, a first blue dopant of the first blue light-emitting layer can have a higher triplet energy level than the first host. A second blue dopant of the second blue light-emitting layer can have a higher triplet energy level than the second host.

According to an aspect of the present disclosure, the second blue dopant can include a different material from the first blue dopant.

According to an aspect of the present disclosure, a triplet energy level of the first blue dopant can be lower than a triplet energy level of the second host.

According to an aspect of the present disclosure, a thickness of the second blue light-emitting layer can be smaller than a thickness of the first blue light-emitting layer.

According to an aspect of the present disclosure, a lower emission stack can be disposed between the first electrode and the upper emission stack. A first charge generation layer can be disposed between the lower emission stack and the upper emission stack.

According to an aspect of the present disclosure, a light-emitting layer of the lower emission stack can be composed of a single layer including a lower blue dopant.

According to an aspect of the present disclosure, a second charge generation layer can be disposed between the first charge generation layer and the upper emission stack. An intermediate emission stack can be disposed between the first charge generation layer and the second charge generation layer. Light emitted from the intermediate emission stack can display a different color from light emitted from the lower emissions stack and light emitted from the upper emission stack.

According to an aspect of the present disclosure, a light-emitting layer of the intermediate emission stack can include a red dopant and a green dopant.

In another embodiment, there is provided a display apparatus comprising a first electrode. An intermediate charge generation layer is disposed on a first electrode. A second electrode is disposed on the intermediate charge generation layer. The second electrode has a smaller work-function than the first electrode. A first blue emission stack is disposed between the first electrode and the intermediate charge generation layer. A second blue emission stack is disposed between the intermediate charge generation layer and the second electrode. The second blue emission stack includes a first upper light-emitting layer and a second upper light-emitting layer contacting a surface of the first upper light-emitting layer toward the second electrode. A host of the second upper light-emitting layer has a higher triplet energy level than a host of the first upper light-emitting layer.

According to an aspect of the present disclosure, the intermediate charge generation layer can have a stacked structure of a n-type charge generating layer and a p-type charge generating layer. The p-type charge generating layer can be disposed between the n-type charge generating layer and the first upper light-emitting layer.

According to an aspect of the present disclosure, the first blue emission stack can include a first lower light-emitting layer and a second lower light-emitting layer. The second lower light-emitting layer can be in contact with a surface of the first lower light-emitting layer toward the second electrode. A host of the second lower light-emitting layer can have a lower triplet energy level than a host of the first lower light-emitting layer.

According to an aspect of the present disclosure, a blue dopant of the first lower light-emitting layer can have a higher triplet energy level than a host of the first lower light-emitting layer. A blue dopant of the second lower light-emitting layer can have a higher triplet energy level than a host of the second lower light-emitting layer.

According to an aspect of the present disclosure, a blue dopant of the first upper light-emitting layer and a blue dopant of the second upper light-emitting layer can have a higher triplet energy level than the host of the second upper light-emitting layer.

In another embodiment, there is provided a display apparatus comprising a cathode electrode and a anode electrode. A light-emitting unit is provided between the cathode electrode and the anode electrode. The light-emitting unit at least includes an upper emission stack which includes a first upper light-emitting layer and a second upper light-emitting layer contacting a surface of the first upper light-emitting layer toward the cathode electrode. A second host of the second upper light-emitting layer has a higher triplet energy level than a first host of the first upper light-emitting layer.

These and other objects of the present application will become more readily apparent from the detailed description given hereinafter. However, it should be understood that the detailed description and specific examples, while indicating various embodiments of the invention, are given by way of illustration only, since various changes and modifications within the spirit and scope of the invention will become apparent to those skilled in the art from this detailed description.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is a view schematically showing a cross-section of the pixel area in the display apparatus according to the embodiment of the present disclosure;

FIG. 4 is an enlarged view of K1 region in FIG. 3;

FIG. 5 is a view showing an energy band diagram of an upper emissions stack in the display apparatus according to the embodiment of the present disclosure;

FIG. 6 is a view showing a relatively energy level according to a material of the upper emissions stack in the display apparatus according to the embodiment of the present disclosure; and

FIGS. 7 to 12 are views showing the display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiments

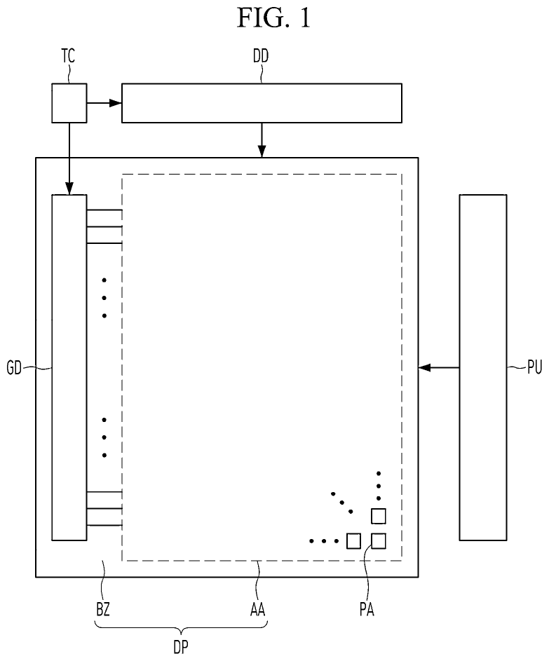

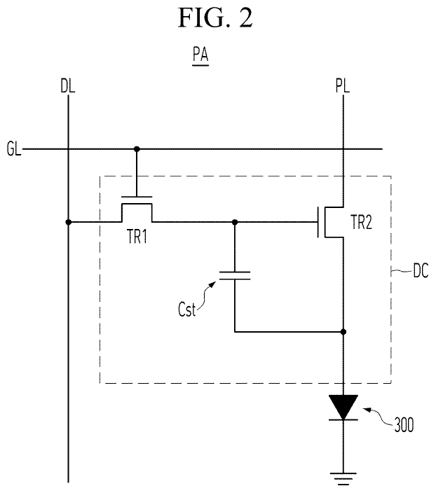

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure can include a display panel DP. The display panel DP can generate an image provided to a user. For example, the display panel DP can include a plurality of pixel area PA. Here, the pixel areas PA can also be referred to pixels. Various signals can be provided in each pixel area PA through signal wirings GL, DL and PL. For example, the signal wirings GL, DL and PL can include gate lines GL sequentially applying a gate signal to each pixel area PA, data lines DL applying a data signal to each pixel area PA, and power voltage supply lines PL supplying a power voltage to each pixel area PA. The gate lines GL can be electrically connected to a gate driver GD, and the data lines DL can be electrically connected to a data driver DD. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC. The power voltage supply lines PL can be electrically connected to a power unit PU.

The display panel DP can include an active area AA in which the pixel areas PA are disposed, and a bezel area BZ being disposed outside the active area AA. For example, the bezel area BZ can surround the active area AA entirely or only in part. The bezel area BZ can be a non-active area or part of the non-active area. At least one of the gate driver GD, the data driver DD, the timing controller TC and the power unit PU can be disposed on the bezel area BZ of the display panel DP. For example, the display apparatus according to the embodiment of the present disclosure can be a GIP (Gate In Panel) type display apparatus in which the gate driver GD is formed on the bezel area BZ of the display panel DP.

Each of the pixel areas PA can realize a specific color. For example, a light-emitting device 300 and a pixel driving circuit DC electrically connected to the light-emitting device 300 can be disposed in each pixel area PA. The pixel driving circuit DC of each pixel area PA can be electrically connected to the signal wirings GL, DL and PL. For example, the pixel driving circuit DC of each pixel area PA can be electrically connected to one of the gate lines GL, one of the data lines DL, and one of the power voltage supply lines PL. The pixel driving circuit DC of each pixel area PA can supply a driving current corresponding to the data signal to the light-emitting device 300 of the corresponding pixel area PA according to the gate signal for one frame. For example, the pixel driving circuit DC of each pixel area PA can include a first thin film transistor TR1, a second thin film transistor TR2 and a storage capacitor Cst.

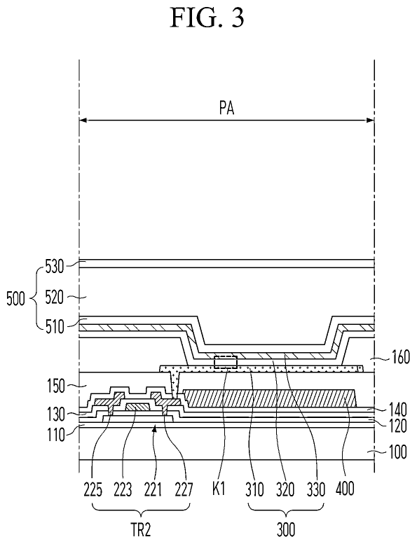

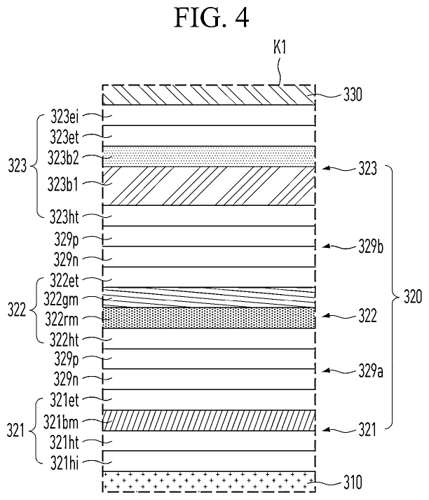

FIG. 3 is a view schematically showing a cross-section of the pixel area in the display apparatus according to the embodiment of the present disclosure. FIG. 4 is an enlarged view of K1 region in FIG. 3.

Referring to FIGS. 2 to 4, the first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. For example, the first gate electrode of each pixel area PA can be electrically connected to the corresponding gate line GL, and the first drain electrode of each pixel area PA can be electrically connected to the corresponding date line DL.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can have a same structure as the first thin film transistor TR1 of the corresponding pixel area PA. For example, the second thin film transistor TR2 of each pixel area PA can include a second semiconductor pattern 221, a second gate electrode 223, a second drain electrode 225 and a second source electrode 227. The second gate electrode 223 of each pixel area PA can be electrically connected to the first source electrode of the corresponding pixel area PA, and the second drain electrode 225 of each pixel area PA can be electrically connected to the corresponding power voltage supply line PL. The light-emitting device 300 of each pixel area PA can be electrically connected to the second source electrode 227 of the corresponding pixel area PA.

The second semiconductor pattern 221 can include a semiconductor material. For example, the second semiconductor pattern 221 can include amorphous silicon (a-Si), polycrystalline silicon (poly-Si) or an oxide semiconductor, such as IGZO. The second semiconductor pattern 221 can include a drain region, a channel region and a source region. The channel region can be disposed between the drain region and the source region. The drain region and the source region can have a smaller resistance than the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be insulated from the second semiconductor pattern 221. For example, the channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. The second drain electrode 225 can be disposed on a different layer from the second gate electrode 223. For example, the second drain electrode 225 can be insulated from the second gate electrode 223. The second drain electrode 225 can be electrically connected to the drain region of the second semiconductor pattern 221.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode. The first drain electrode can be insulated from the first gate electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be insulated from the second gate electrode 223. The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225. The second source electrode 227 can be electrically connected to the source region of the second semiconductor pattern 221.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode. The first source electrode can be insulated from the first drain electrode.

The storage capacitor Cst of each pixel area PA can maintain a signal applied to the second gate electrode 223 of the corresponding pixel area PA for one frame. For example, the storage capacitor Cst of each pixel area PA can be electrically connected between the second gate electrode 223 and the second source electrode 227 of the corresponding pixel area PA. The storage capacitor Cst of each pixel area PA can have a stacked structure of capacitor electrodes. The storage capacitor Cst of each pixel area PA can be formed by using a process of forming the first thin film transistor TR1 and the second thin film transistor TR2 of the corresponding pixel area PA. For example, the storage capacitor Cst of each pixel area PA can include a first capacitor electrode formed simultaneously with the second gate electrode 233 of the corresponding pixel area PA, and a second capacitor electrode formed simultaneously with the second source electrode 227 of the corresponding pixel area PA.

The pixel driving circuit DC of each pixel area PA can be disposed on a device substrate 100. The device substrate 100 can include an insulating material. For example, the device substrate 100 can include glass or plastic. A plurality of insulating layers 110, 120, 130, 140, 150 and 160 for preventing unnecessary electrical connection in each pixel area PA can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed close to the device substrate 100. The buffer insulating layer 110 can prevent pollution due to the device substrate 100 in a process of forming the first thin film transistor TR1 and the second thin film transistor TR2 in each pixel area PA. For example, an upper surface of the device substrate 100 toward the first thin film transistor TR1 and the second thin film transistor TR2 of each pixel area PA can be completely covered by the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a stacked structure of an inorganic insulating layer made of silicon oxide (SiOx) and an inorganic insulating layer made of silicon nitride (SiNx).

The gate insulating layer 120 can be disposed on the buffer insulating layer 110. For example, the buffer insulating layer 110 can be disposed between the device substrate 100 and the gate insulating layer 120. The first gate electrode and the second gate electrode 223 of each pixel area PA can be insulated from the first semiconductor pattern and the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. For example, the gate insulating layer 120 can be disposed between the buffer insulating layer 110 and the interlayer insulating layer 130. The first drain electrode, the first source electrode, the second drain electrode 225 and the second source electrode 227 of each pixel area PA can be insulated from the first gate electrode and the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material, such as silicon oxide (SiOx) and silicon nitride (SiNx).

The device passivation layer 140 can be disposed on the interlayer insulating layer 130. For example, the interlayer insulating layer 130 can be disposed between the gate insulating layer 120 and the device passivation layer 140. The device passivation layer 140 can prevent damage of the pixel driving circuit DC in each pixel area PA due to external impact and moisture. For example, the device passivation layer 140 can be a linear layer extending along a surface of each pixel driving circuit DC opposite to the device substrate 100. The first drain electrode, the first source electrode, the second drain electrode 225 and the second source electrode 227 of each pixel area PA can be covered by the device passivation layer 140. The device passivation layer 140 can include an insulating material. For example, the device passivation layer 140 can be an inorganic insulating material, such as silicon oxide (SiOx) and silicon nitride (SiNx).

The planarization layer 150 can be disposed on the device passivation layer 140. For example, the device passivation layer 140 can be disposed between the interlayer insulating layer 130 and the planarization layer 150. The planarization layer 150 can remove a thickness difference due to the pixel driving circuit DC of each pixel area PA. For example, an upper surface of the planarization layer 150 opposite to the device substrate 100 can be a flat surface. The planarization layer 150 can include an insulating material. The planarization layer 150 can include a different material from the device passivation layer 140. The planarization layer 150 can include a material having a relatively high fluidity. For example, the planarization layer 150 can include an organic insulating material.

The light-emitting device 300 of each pixel area PA can be disposed on the planarization layer 150. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked.

The first electrode 310 and the second electrode 330 can include a conductive material. The second electrode 330 can include a different material from the first electrode 310. A transmittance of the first electrode 310 can be greater than a transmittance of the second electrode 330. The second electrode 330 can have a higher reflectance than the first electrode 310. For example, the first electrode 310 can be a transparent electrode made of a transparent conductive material, such as ITO and IZO, and the second electrode 330 can include a metal. The second electrode 330 can have a smaller work-function than the first electrode 310. For example, the first electrode 310 can function as an anode electrode, and the second electrode 330 can function as a cathode electrode.

The light-emitting unit 320 can generate light having luminance corresponding to a voltage difference between the first electrode 310 and the second electrode 330. The light-emitting unit 320 can include a plurality of emission stack 321, 322 and 323, and at least one charge generation layer 329a and 329b. For example, the light-emitting unit 320 can include a lower emission stack 321, a first charge generation layer 329a, an intermediate emission stack 322, a second charge generation layer 329b and an upper emission stack 323, which are sequentially stacked.

Each of the first charge generation layer 329a and the second charge generation layer 329b can supply electrons or holes to adjacent emission stack 321, 322 and 323. For example, each of the first charge generation layer 329a and the second charge generation layer 329b can have a stacked structure of a n-type charge generating layer 329n and a p-type charge generating layer 329p. The n-type charge generating layer 329n can be disposed close to the first electrode 310, and the p-type charge generating layer 329p can be disposed close to the second electrode 330. For example, the p-type charge generating layer 329p of each of the first charge generation layer 329a and the second charge generation layer 329b can be disposed between the corresponding n-type charge generating layer 329n and the second electrode 330. Thus, in the display apparatus according to the embodiment of the present disclosure, electrons and holes can be supplied in a balanced manner to each emission stack 321, 322 and 323.

The lower emission stack 321 can be disposed between the first electrode 310 and the first charge generation layer 329a. The intermediate emission stack 322 can be disposed between the first charge generation layer 329a and the second charge generation layer 329b. The upper emission stack 323 can be disposed between the second charge generation layer 329b and the second electrode 330. Each of the lower emission stack 321, the intermediate emission stack 322 and the upper emission stack 323 can include at least one light-emitting layer 321bm, 322rm, 322gm, 323b1 and 323b2. For example, the lower emission stack 321 can include a lower hole injection layer 321hi, a lower hole transport layer 321ht, a lower light-emitting layer 321bm and a lower electron transport layer 321et, which are sequentially stacked on the first electrode 310. The intermediate emission stack 322 can include an intermediate hole transport layer 322ht, a first intermediate light-emitting layer 322rm, a second intermediate light-emitting layer 322gm, and an intermediate electron transport layer 322et, which are sequentially stacked on the first charge generation layer 329a. The upper emission stack 323 can include an upper hole transport layer 323ht, a first upper light-emitting layer 323b1, a second upper light-emitting layer 323b2, an upper electron transport layer 323et and an upper electron injection layer 323ei, which are sequentially stacked on the second charge generation layer 329b. The second electrode 330 can be disposed on the upper electron injection layer 323ei.

Each of the light-emitting layers 321bm, 322rm, 322gm, 323b1 and 323b2 can generate light using energy by the recombination of electrons and holes. For example, each of the light-emitting layers 321bm, 322rm, 322gm, 323b1 and 323b2 can include a host and a dopant doped into the host. Here, the term ‘doped’ means that a second material having physical properties different from a first material was added to a layer in which the first material occupies most of the weight ratio. For example, the dopant of each light-emitting layer 321bm, 322rm, 322gm, 323b1 and 323b2 can have a weight ratio of less than 30% of the corresponding light-emitting layer 321bm, 322rm, 322gm, 323b1 and 323b2. And, a Lowest Unoccupied Molecular Orbital (LUMO) energy level and a Highest Occupied Molecular Orbital (HOMO) energy level of each light-emitting layer 321bm, 322rm, 322gm, 323b1 and 323b2 can mean a LUMO energy level and a HOMO energy level of the host occupying most of the weight ratio in the corresponding light-emitting layer 321bm, 322rm, 322gm, 323b1 and 323b2.

The light emitted from the light-emitting unit 320 can display a white color. At least one of the light-emitting layers 321bm, 322rm, 322gm, 323b1 and 323b2 can generate light having a different wave-length range from another light-emitting layer 321bm, 322rm, 322gm, 323b1 and 323b2. For example, the light emitted from the intermediate emission stack 322 can display a different color from the light emitted from the lower emission stack 321 and the light emitted from the upper emission stack 323. The first upper light-emitting layer 323b1 and the second upper light-emitting layer 323b2 of the upper emission stack 323 can generate light displaying a same color as the lower light-emitting layer 321bm of the lower emission stack 321. For example, the light emitted from the lower emission stack 321 and the light emitted from the upper emission stack 323 can display a blue color. The light emitted from the intermediate emission stack 322 can display a color in a complementary color relationship with blue color. For example, the intermediate emission stack 322 can generate the light displaying a yellow color.

The lower light-emitting layer 321bm can generate the light using holes supplied through the lower hole injection layer 321hi and the lower hole transport layer 321ht from the first electrode 310 and electrons supplied through the n-type charge generating layer 329n of the first charge generation layer 329a. The lower light-emitting layer 321bm can include a lower host and a lower blue dopant doped into the lower host. The lower blue dopant can be a fluorescent dopant. For example, the lower host of the lower light-emitting layer 321bm can include one of naphthalene moiety, anthracene, pyrene and phenanthrene, and the lower blue dopant of the lower light-emitting layer 321bm can be a pyrene-based blue fluorescent dopant or a boron-based blue fluorescent dopant.

The first intermediate light-emitting layer 322rm and the second intermediate light-emitting layer 322gm can generate light using holes supplied through the intermediate hole transport layer 322ht from the p-type charge generating layer 329p of the first charge generation layer 329 and electrons supplied through the intermediate electron transport layer 322et from the n-type charge generating layer 329n of the second charge generation layer 329b. For example, the first intermediate light-emitting layer 322rm can include a first intermediate host and a first intermediate dopant doped into the first intermediate host, and the second intermediate light-emitting layer 322gm can include a second intermediate host and a second intermediate dopant doped into the second intermediate host, and the first intermediate dopant and the second intermediate dopant can include a different material from the lower blue dopant. The light generated by the second intermediate light-emitting layer 322gm can display a different color from the light generated by the first intermediate light-emitting layer 322rm. The second intermediate dopant can include a different material from the first intermediate dopant. For example, the first intermediate dopant can include a red dopant, and the second intermediate dopant can include a green dopant. The first intermediate dopant and the second intermediate dopant can include phosphorescent dopant. For example, the first intermediate host of the first intermediate light-emitting layer 322rm and the second intermediate host of the second intermediate light-emitting layer 322gm can include CBP (carbazole biphenyl) or mCP (1,3-bis(carbazol-9-yl), the first intermediate dopant of the first intermediate light-emitting layer 322rm can be a red dopant including at least one selected from the group consisting of Ir(Piq)3(Tris(1-phenylisoquinoline) iridium (III)), Ir(piq)2(acac)(Bis(1-phenylisoquinoline)(acetylacetonate)iridiumIII)), Ir(btp)2(acac)(Bis)2-benzo[b]thiophen-2-yl-pyridine) (acetylacetonate) iridiumIII)), Ir(BT)2(acac)(Bis(2-phenylbenzothazolato)(acetylacetonate)iridiumIII)), and the second intermediate dopant of the second intermediate light-emitting layer 322gm can be a green dopant including at least one selected from the group consisting of Ir(ppy)3(fac tris(2-phenylpyridine) iridium), Ir(ppy)2(acac), Ir(mpyp)3. The second intermediate host of the second intermediate light-emitting layer 322gm can include a different material from the first intermediate host of the first intermediate light-emitting layer 322rm.

The first upper light-emitting layer 323b1 and the second upper light-emitting layer 323b2 can generate light using holes supplied through the upper hole transport layer 323ht from the p-type charge generating layer 329p of the second charge generation layer 329b and electrons supplied through the upper electron injection layer 323ei and the upper electron transport layer 323et from the second electrode 330. The second upper light-emitting layer 323b2 can be in direct contact with the first upper light-emitting layer 323b1. For example, an upper surface of the first upper light-emitting layer 323b1 toward the second electrode 330 can be in contact with a lower surface of the second upper light-emitting layer 323b2 toward the first electrode 310. The light generated by the second upper light-emitting layer 323b2 can display a same color as the light generated by the first upper light-emitting layer 323b1. For example, the first upper light-emitting layer 323b1 can include a first upper host and a first blue dopant doped into the first upper host, and the second upper light-emitting layer 323b2 can include a second upper host and a second blue dopant doped into the second upper host. The first blue dopant and the second blue dopant can be a fluorescent material. The light generated by the second upper light-emitting layer 323b2 can have a same wave-length range as the light generated by the first upper light-emitting layer 323b1. For example, the second blue dopant can be made of a same material as the first blue dopant.

The first upper host and the second upper host can have a relatively high holes transport properties. Excitons generated by the combination of holes and electrons can be divided into singlet excitons having paired spin form and triplet excitons having unpaired spin form, depending on the spin arrangement. In the emission of fluorescent materials, the contribution of singlet excitons is higher than the contribution of triplet excitons. Thus, in the display apparatus according to the embodiment of the present disclosure, the triplet excitons can be accumulated in the first upper light-emitting layer 323b1 and the second upper light-emitting layer 323b2. For example, in the display apparatus according to the embodiment of the present disclosure, the triplet excitons generated in the first upper light-emitting layer 323b1 can be accumulated at an interface between the first upper light-emitting layer 323b1 and the second upper light-emitting layer 323b2.

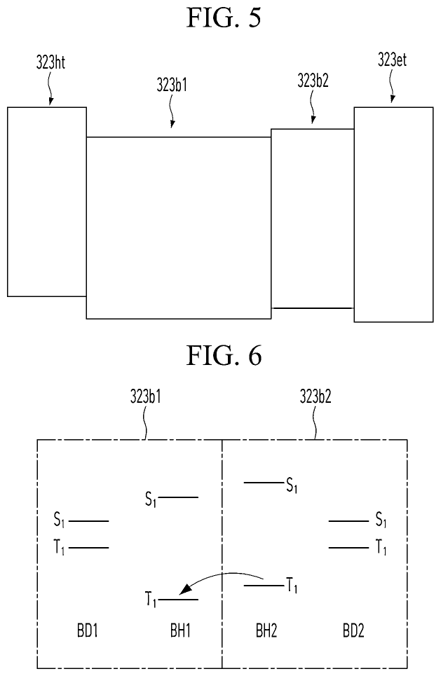

FIG. 5 is a view showing an energy band diagram of an upper emissions stack 323 in the display apparatus according to the embodiment of the present disclosure. FIG. 6 is a view showing a relatively energy level according to a material of the upper emissions stack 323 in the display apparatus according to the embodiment of the present disclosure. S₁ in FIG. 6 represents a singlet energy level.

Referring to FIGS. 5 and 6, the second upper host BH2 of the second upper light-emitting layer 323b2 can have a higher triplet energy level Tl than the first upper host BH1 of the first upper light-emitting layer 323b1. The second upper host BH2 can include a different material from the first upper host BH1. For example, the first upper host BH1 can include an anthracene-based material, and the second upper host BH2 can include a pyrene-based material. Thus, in the display apparatus according to the embodiment of the present disclosure, triplet excitons generated in the second upper light-emitting layer 323b2 can be transferred to the first upper light-emitting layer 323b1 through dexter energy transfer. For example, in the display apparatus according to the embodiment of the present disclosure, the accumulation of triplet excitons at an upper surface of the second upper light-emitting layer 323b2 toward the second electrode 330 can be prevented. Therefore, in the display apparatus according to the embodiment of the present disclosure, the deterioration and the damage of the upper electron transport layer 323et contacting the upper surface of the second upper light-emitting layer 323b2 due to the accumulation of triplet excitons can be prevented. And, in the display apparatus according to the embodiment of the present disclosure, life-span of the upper emission stack 323 can be increased.

Triplet excitons accumulated at an interface between the first upper light-emitting layer 323b1 and the second upper light-emitting layer 323b2 can contribute to the emission of the first blue dopant BD1 and/or the emission of the second blue dopant BD2. For example, in the display apparatus according to the embodiment of the present disclosure, triplet excitons generated in the second upper light-emitting layer 323b2 can be recycled. Thus, in the display apparatus according to the embodiment of the present disclosure, the efficiency of the upper emission stack 323 can be improved.

The first blue dopant BD1 of the first upper light-emitting layer 323b1 and the second blue dopant BD2 of the second upper light-emitting layer 323b2 can have a higher triplet energy level than the second upper host BH2 of the second upper light-emitting layer 323b2. Thus, in the display apparatus according to the embodiment of the present disclosure, deterioration of the first blue dopant BD1 and/or the second blue dopant BD2 due to the trap of singlet excitons and/or triplet excitons can be delayed. Therefore, in the display apparatus according to the embodiment of the present disclosure, the efficiency and life-span of the upper emission stack 323 can be improved.

The LUMO energy level of the upper electron transport layer 323et can be higher than the LUMO energy level of the second upper light-emitting layer 323b2. Here, since a LUMO energy level is based on the vacuum level, the expression that ‘the LUMO energy level is high’ means that the absolute value of the LUMO energy level is small. For example, in the display apparatus according to the embodiment of the present disclosure, the LUMO energy level of the upper electron transport layer 323et can have an absolute value smaller than the LUMO energy level of the second upper light-emitting layer 323b2. Thus, in the display apparatus according to the embodiment of the present disclosure, electrons can be smoothly supplied to the second upper light-emitting layer 323b2 through the upper electron transport layer 323et.

The HOMO energy level of the upper electron transport layer 323et can be lower than the HOMO energy level of the second upper light-emitting layer 323b2. Here, since a HOMO energy level is based on the vacuum level, the expression that ‘the HOMO energy level is low’ means that the absolute value of the HOMO energy level is great. For example, in the display apparatus according to the embodiment of the present disclosure, the HOMO energy level of the upper electron transport layer 323et can have an absolute value greater than the HOMO energy level of the second upper light-emitting layer 323b2. Thus, in the display apparatus according to the embodiment of the present disclosure, holes provided to the second upper light-emitting layer 323b2 may not flow smoothly into the upper electron transport layer 323et. For example, in the display apparatus according to the embodiment of the present disclosure, the upper electron transport layer 323et can function as a hole blocking layer. Therefore, in the display apparatus according to the embodiment of the present disclosure, the efficiency of the upper emission stack can be effectively improved.

Table 1 below shows a relatively external quantum efficiency (EQE) and a life-span (T95) of the light-emitting unit 320 according to a thickness ratio of the first upper light-emitting layer 323b1 and the second upper light-emitting layer 323b2. Here, T95 means time until the luminance decreases to 95% of the initial value.

TABLE 1

| Thickness ratio of First upper light-emitting layer and | | |
|---|---|---|
| Second upper light-emitting layer | EQE | T95 |
| 9:1 | 101% | 121% |
| 8:2 | 103% | 165% |
| 6:4 | 102% | 143% |
| 5:5 | 97% | 115% |

Referring to Table 1 above, if the second upper light-emitting layer 323b2 has a thickness of 10% to 40% of the first upper light-emitting layer 323b1, both the efficiency and life-span of the light-emitting unit 320 can be improved. And, if the second upper light-emitting layer 323b2 has a thickness of 50% of the first upper light-emitting layer 323b1, the life-span of the light-emitting unit 320 can be increased, but the efficiency of the light-emitting unit 320 can be decreased. Thus, in the display apparatus according to the embodiment of the present disclosure, the second upper light-emitting layer 323b2 can have a thinner thickness than the first upper light-emitting layer 323b1. For example, in the display apparatus according to the embodiment of the present disclosure, the second upper light-emitting layer 323b2 can have a thickness of 10% to 40% of the first upper light-emitting layer 323b1. Therefore, in the display apparatus according to the embodiment of the present disclosure, both the efficiency and life-span of the light-emitting unit 320 can be improved.

In the display apparatus according to embodiment of the present disclosure, color filters 400 can be disposed between the device passivation layer 140 and the planarization layer 150 of each pixel area PA, as shown in FIG. 3. The color filter 400 of each pixel area PA can be disposed on a path of the light emitted from the light-emitting device 300 of the corresponding pixel area PA. For example, the color filter 400 of each pixel area PA can overlap the light-emitting device 300 of the corresponding pixel area PA. The light generated by the light-emitting unit 320 of each pixel area PA can be emitted outside through the first electrode 310, the color filter 400 and the device substrate 100 of the corresponding pixel area PA. Thus, in the display apparatus according to the embodiment of the present disclosure, an image composed of various colors can be provided to the user. A thickness difference due to the color filter 400 of each pixel area PA can be removed by the planarization layer 150.

The bank insulating layer 160 can be disposed on the planarization layer 150. The bank insulating layer 160 can define an emission area in each pixel area PA. For example, the bank insulating layer 160 can include openings overlapping with the color filter 400 of each pixel area PA. The light-emitting device 300 of each pixel area PA can be controlled independently from the light-emitting device 300 of adjacent pixel area PA. For example, the first electrode 310 of each pixel area PA can be insulated from the first electrode 310 of adjacent pixel area PA by the bank insulating layer 160. The first electrode 310 of each pixel area PA can be spaced apart from the first electrode 310 of adjacent pixel area PA. For example, an edge of the first electrode 310 in each pixel area PA can be covered by the bank insulating layer 160. The bank insulating layer 160 can include an insulating material. For example, the bank insulating layer 160 can be an organic insulating material. The bank insulating layer 160 can include a different material from the planarization layer 150.

The light-emitting unit 320 of each pixel area PA can have a same structure as the light-emitting unit 320 of adjacent pixel area PA. The light-emitting unit 320 of each pixel area PA can be formed by a same process of the light-emitting unit 320 of adjacent pixel area PA. For example, the light-emitting unit 320 of each pixel area PA can be formed simultaneously with the light-emitting unit 320 of adjacent pixel area PA. The light-emitting unit 320 of each pixel area PA can be in direct contact with the light-emitting unit 320 of adjacent pixel area PA. For example, the light-emitting unit 320 of each pixel area PA can extend onto the bank insulating layer 160. Thus, in the display apparatus according to the embodiment of the present disclosure, a process of forming the light-emitting unit 320 in each pixel area PA can be simplified.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA. For example, the second electrode 330 of each pixel area PA can extend onto the bank insulating layer 160. Thus, in the display apparatus according to the embodiment of the present disclosure, a process of forming the second electrode 330 in each pixel area PA can be simplified. And, in the display apparatus according to the embodiment of the present disclosure, the luminance of the light emitted from the light-emitting device 300 of each pixel area PA can be adjusted by the data signal applied to the pixel driving circuit DC of the corresponding pixel area PA.

An encapsulation unit 500 can be disposed on the light-emitting device 300 of each pixel area PA. The encapsulation unit 500 can prevent damage of the light-emitting devices 300 due to external moisture and impact. The encapsulation unit 500 can have a multi-layer structure. For example, the encapsulation unit 500 can include a first encapsulating layer 510, a second encapsulating layer 520 and a third encapsulating layer 530, which are sequentially stacked. The first encapsulating layer 510, the second encapsulating layer 520 and the third encapsulating layer 530 can include an insulating material. The second encapsulating layer 520 can include a different material from the first encapsulating layer 510 and the third encapsulating layer 530. For example, the first encapsulating layer 510 and the third encapsulating layer 530 can include an inorganic insulating material, such as silicon oxide (SiOx) and silicon nitride (SiNx), and the second encapsulating layer 520 can include an organic insulating material. A thickness difference due to the light-emitting device 300 of each pixel area PA can be removed by the second encapsulating layer 520. For example, an upper surface of the encapsulation unit 500 opposite to the device substrate 100 can be a flat surface. Thus, in the display apparatus according to the embodiment of the present disclosure, the damage of the light-emitting device 300 in each pixel area PA due to the external moisture and impact can be effectively prevented.

Accordingly, in the display apparatus according to the embodiment of the present disclosure, the light-emitting device 300 of each pixel area PA can include the light-emitting unit 320 between the first electrode 310 and the second electrode 330, the light-emitting unit 320 generating white light can include the lower emission stack 321, the intermediate emission stack 322 and the upper emission stack 323, the upper emission stack 323 disposed close to the second electrode 330, which functions as a cathode electrode can have a stacked structure of the first upper light-emitting layer 323b1 including the first upper host BH1 and the first blue dopant BD1 and the second upper light-emitting layer 323b2 including the second upper host BH2 and the second blue dopant BD2, the second upper light-emitting layer 323b2 can be in contact with the upper surface of the first upper light-emitting layer 323b1 toward the second electrode 330, the second upper host BH2 of the second upper light-emitting layer 323b2 can have a higher triplet energy level than the first upper host BH1 of the first upper light-emitting layer 323b1. Thus, in the display apparatus according to the embodiment of the present disclosure, triplet excitons generated in the second upper light-emitting layer 323b2 can be transferred to the first upper light-emitting layer 323b1. For example, in the display apparatus according to the embodiment of the present disclosure, the accumulation of triplet excitons at the upper surface of the second upper light-emitting layer 323b2 toward the second electrode 330 can be prevented. Therefore, in the display apparatus according to the embodiment of the present disclosure, the efficiency and life-span of the light-emitting device 300 in each pixel area PA can be improved.

The display apparatus according to the embodiment of the present disclosure is described that the pixel driving circuit DC of each pixel area PA can consist of the first thin film transistor TR1, the second thin film transistor TR2 and the storage capacitor Cst. However, in the display apparatus according to another embodiment of the present disclosure, the pixel driving circuit DC of each pixel area PA can include at least one thin film transistor. For example, in the display apparatus according to another embodiment of the present disclosure, the pixel driving circuit DC of each pixel area PA can include the first thin film transistor TR1, the second thin film transistor TR2, the storage capacitor Cst and a third thin film transistor. The third thin film transistor can initialize the storage capacitor Cst according to the gate signal. The third thin film transistor can have a same structure as the first thin film transistor TR1 and the second thin film transistor TR2. For example, a third gate electrode of the third thin film transistor can be electrically connected to the corresponding gate line GL, a third drain electrode of the third thin film transistor can be electrically connected to an initial line applying an initial signal, and a third source electrode of the third thin film transistor can be electrically connected to the storage capacitor Cst. Thus, in the display apparatus according to another embodiment of the present disclosure, the degree of freedom in configuring each pixel driving circuit DC can be improved.

In the display apparatus according to the embodiment of the present disclosure, the location and the electric connection of the first drain electrode, the first source electrode, the second drain electrodes 225 and the second source electrode 227 in each pixel driving circuit DC can vary depending on the configuration of the corresponding pixel driving circuit DC and/or the type of the corresponding thin film transistors TR1 and TR2. For example, in the display apparatus according to another embodiment of the present disclosure, the second gate electrode 223 of each pixel driving circuit DC can be electrically connected to the first drain electrode of the corresponding pixel driving circuit DC. Thus, in the display apparatus according to another embodiment of the present disclosure, the degree of freedom in the configuration of each pixel driving circuit DC and the type of each thin film transistor TR1 and TR2 can be improved.

The display apparatus according to the embodiment of the present disclosure is described that the second blue dopant can include a same material as the first blue dopant. However, in the display apparatus according to another embodiment of the present disclosure, the second blue dopant of the second upper light-emitting layer 323b2 may include a different material from the first blue dopant of the first upper light-emitting layer 323b1, and the second blue dopant of the second upper light-emitting layer 323b2 can have a different triplet energy level from the first blue dopant of the first upper light-emitting layer 323b1. For example, in the display apparatus according to another embodiment of the present disclosure, the first blue dopant can have a higher triplet energy level than the first upper host, the second blue dopant can have a higher triplet energy level than the second upper host, and the triplet energy level of the first blue dopant can be lower than the triplet energy level of the second upper host. Thus, in the display apparatus according to another embodiment of the present disclosure, deterioration of the first blue dopant and/or the second blue dopant due to the trap of singlet excitons and/or triplet excitons can be delayed. And, in the display apparatus according to another embodiment of the present disclosure, the degree of freedom in the material of the first blue dopant and the second blue dopant can be improved.

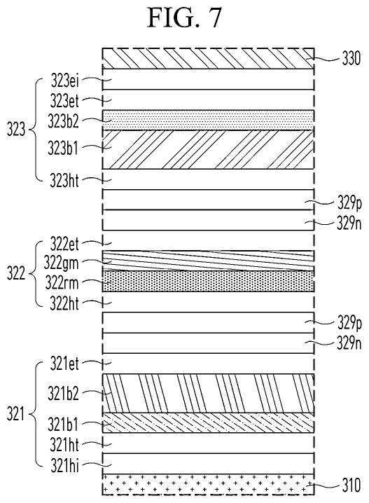

The display apparatus according to the embodiment of the present disclosure is described that the lower light-emitting layer 321bm of the lower emission stack 321 can be a single layer including the lower blue dopant. For example, in the display apparatus according to the embodiment of the present disclosure, a thickness of the lower light-emitting layer 321bm can be smaller than the sum of a thickness of the first upper light-emitting layer 323b1 and a thickness of the second upper light-emitting layer 323b2. However, in the display apparatus according to another embodiment of the present disclosure, the lower emission stack 321 can have a stacked structure of a first lower light-emitting layer 321b1 and a second lower light-emitting layer 321b2, and the upper emission stack 323 can have a stacked structure of the first upper light-emitting layer 323b1 and the second upper light-emitting layer 323b2, as shown in FIG. 7. The second lower light-emitting layer 321b2 can be in direct contact with an upper surface of the first lower light-emitting layer 321b1 toward the second electrode 330, and the second upper light-emitting layer 323b2 can be in direct contact with the upper surface of the first upper light-emitting layer 323b1 toward the second electrode 330. For example, in the display apparatus according to another embodiment of the present disclosure, a sum of a thickness of the first lower light-emitting layer 321b1 and a thickness of the second lower light-emitting layer 321b2 can be a same as a sum of a thickness of the first upper light-emitting layer 323b1 and a thickness of the second upper light-emitting layer 323b2.

The first lower light-emitting layer 321b1 can include a first lower host and a first lower dopant doped into the first lower host. The second lower light-emitting layer 321b2 can include a second lower host and a second lower dopant doped into the second lower host. The second lower dopant can include a same material as the first lower dopant. For example, the first lower dopant and the second lower dopant can include a same material as the first blue dopant and the second blue dopant of the upper emission stack 323.

The relationship between the triplet energy level of the first lower host and the triplet energy level of the second lower host can be different from the relationship between the triplet energy level of the first upper host and the triplet energy level of the second upper host. Table 2 below shows a relatively external quantum efficiency (EQE) and a life-span (T95) according to a thickness ratio of the first lower light-emitting layer 321b1 and the second lower light-emitting layer 321b2 in a display apparatus in which the lower emission stack 321 has a stacked structure of the first lower light-emitting layer 321b1 and the second lower light-emitting layer 321b2, the intermediate emission stack 322 includes a first intermediate light-emitting layer 322rm as a red light-emitting layer and a second intermediate light-emitting layer 322gm as a green light-emitting layer, and the upper emission stack 323 includes a single blue light-emitting layer, wherein the second lower host of the second lower light-emitting layer 321b2 has a higher triplet energy level than the first lower host of the first lower light-emitting layer 321b1.

TABLE 2

| Thickness ratio of First lower light-emitting layer and | | |
|---|---|---|
| Second lower light-emitting layer | EQE | T95 |
| 9:1 | 95% | 28% |
| 8:2 | 96% | 32% |
| 6:4 | 93% | 25% |

Referring to Table 2 above, the life-span of the light-emitting unit 320 can be greatly reduced, regardless of the thickness ratio of the first lower light-emitting layer 321b1 and the second lower light-emitting layer 321b2. Table 2 can be interpreted that if the second lower host of the second lower light-emitting layer 321b2 has a higher triplet energy level than the first lower host of the first lower light-emitting layer 321b1, triplet excitons in the first lower light-emitting layer 321b1 are accumulated at a lower surface of the first lower light-emitting layer 321b1 toward the first electrode 310, and the lower hole transport layer 321ht contacting the lower surface of the first lower light-emitting layer 321b1 is deteriorated by the accumulation of triplet excitons. Thus, in the display apparatus according to another embodiment of the present disclosure, the second lower host of the second lower light-emitting layer 321b2 can have a lower triplet energy level than the first lower host of the first lower light-emitting layer 321b1. For example, in the display apparatus according to another embodiment of the present disclosure, triplet excitons generated in the first lower light-emitting layer 321b1 can be transferred to the second lower light-emitting layer 321b2. Therefore, in the display apparatus according to another embodiment of the present disclosure, deterioration of life-span in the light-emitting unit 320 due to the accumulation of triplet excitons can be prevented. The second lower light-emitting layer 321b2 can have a greater thickness than the first lower light-emitting layer 321b1.

The first lower host and the second lower host can include a different material from the first upper host and the second upper host. For example, the first lower host and the second lower host can include a material having relatively high electron transport properties. The second lower host can include a different material from the first lower host. For example, the first lower host can include naphthalene-based material, and the second lower host can include one of anthracene, pyrene and phenanthrene. The first lower dopant of the first lower light-emitting layer 321b1 and the second lower dopant of the second lower light-emitting layer 321b2 can have a higher triplet energy level than the first lower host. That is, the first lower dopant of the first lower light-emitting layer 321b1 may have a higher triplet energy level than the first lower host, and the second lower dopant of the second lower light-emitting layer 321b2 may have a higher triplet energy level than the second lower host. Thus, in the display apparatus according to another embodiment of the present disclosure, the efficiency and life-span of the light-emitting unit 320 can be greatly improved.

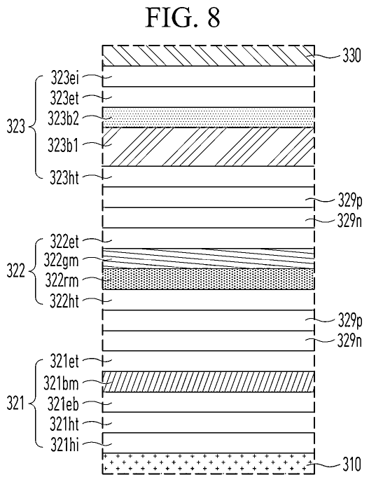

The display apparatus according to the embodiment of the present disclosure is described that the lower light-emitting layer 321bm can be in direct contact with the lower hole transport layer 321ht. However, in the display apparatus according to another embodiment of the present disclosure, the lower emission stack 321 can include an electron blocking layer 321eb between the lower hole transport layer 321ht and the lower light-emitting layer 321bm, as shown in FIG. 8. Thus, in the display apparatus according to another embodiment of the present disclosure, the emission efficiency of the lower light-emitting layer 321bm can be improved. Therefore, in the display apparatus according to another embodiment of the present disclosure, efficiency and life-span of the light-emitting device in each pixel area can be improved.

The display apparatus according to the embodiment of the present disclosure is described that the lower emission stack 321 can include a single lower hole transport layer 321ht. However, in the display apparatus according to another embodiment of the present invention, the lower emission stack 321 can include a plurality of the lower hole transport layers 321ht. Thus, in the display apparatus according to another embodiment of the present disclosure, holes supplied to the lower light-emitting layer 321bm can be controlled by an interaction between the hole injection layer 321hi and the lowest lower hole transport layer 321ht of the lower emission stack 321 and a difference in HOMO energy level between the lower hole transport layers 321ht. For example, in the display apparatus according to another embodiment of the present disclosure, a region in which electrons and holes are recombined in the lower light-emitting layer 321bm can be controlled by layers disposed between the first electrode 310 and the lower light-emitting layer 321bm. Therefore, in the display apparatus according to another embodiment of the present disclosure, life-span of the light-emitting device in each pixel area can be effectively improved.

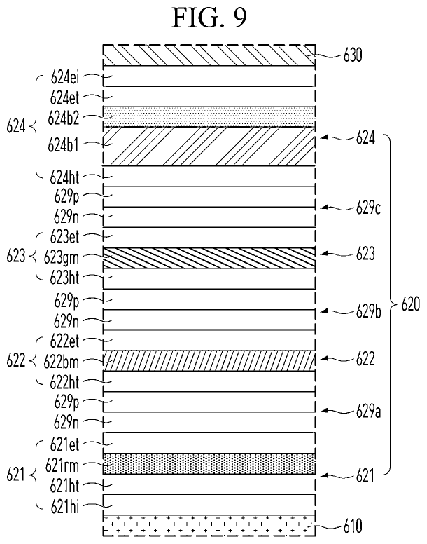

The display apparatus according to the embodiment of the present disclosure is described that the light-emitting unit 320 can include three emission stacks 321, 322 and 323. However, in the display apparatus according to another embodiment of the present invention, the light-emitting unit 320 emitting white light can include at least two emission stacks. For example, in the display apparatus according to another embodiment of the present disclosure, the light-emitting unit 620 between the first electrode 610 and the second electrode 630 can include a red emission stack 621, a first charge generation layer 629a, a lower blue emission stack 622, a second charge generation layer 629b, a green emission stack 623, a third charge generation layer 629c and an upper blue emission stack 624, as shown in FIG. 9.

Each of the first charge generation layer 629a, the second charge generation layer 629b and the third charge generation layer 629c can supply electrons or holes to adjacent emission stack 621, 622, 623 and 624. For example, each of the first charge generation layer 629a, the second charge generation layer 629b and the third charge generation layer 629c can have a stacked structure of a n-type charge generating layer 629n and a p-type charge generating layer 629p.

The red emission stack 621 between the first electrode 610 and the first charge generation layer 629a can include a hole injection layer 621hi, a first hole transport layer 621ht, a red light-emitting layer 621rm and a first electron transport layer 621et. The red light-emitting layer 621rm can have a single layer structure including a red host and a red dopant.

The lower blue emission stack 622 between the first charge generation layer 629a and the second charge generation layer 629b can include a second hole transport layer 622ht, a lower blue light-emitting layer 622bm and a second electron transport layer 622et. The lower blue light-emitting layer 622bm can have a single layer structure including a lower host and a lower blue dopant.

The green emission stack 623 between the second charge generation layer 629b and the third charge generation layer 629c can include a third hole transport layer 623ht, a green light-emitting layer 623gm and a third electron transport layer 623et. The green light-emitting layer 623gm can have a single layer structure including a green host and a green dopant.

The upper blue emission stack 624 between the third charge generation layer 629c and the second electrode 630 can include a fourth hole transport layer 624ht, a first upper light-emitting layer 624b1, a second upper light-emitting layer 624b2, a fourth electron transport layer 624et and an electron injection layer 624ei. The first upper light-emitting layer 624b1 can include a first upper host and a first blue dopant. The second upper light-emitting layer 624b2 can include a second upper host and the second blue dopant. The second upper host can have a higher triplet energy level than the first upper host. The first blue dopant and the second blue dopant can have a higher triplet energy level than the second upper host. Thus, in the display apparatus according to another embodiment of the present disclosure, the efficiency and life-span of the light-emitting unit 620 can be increased, and color characteristics of white light emitted from the light-emitting unit 620 can be improved.

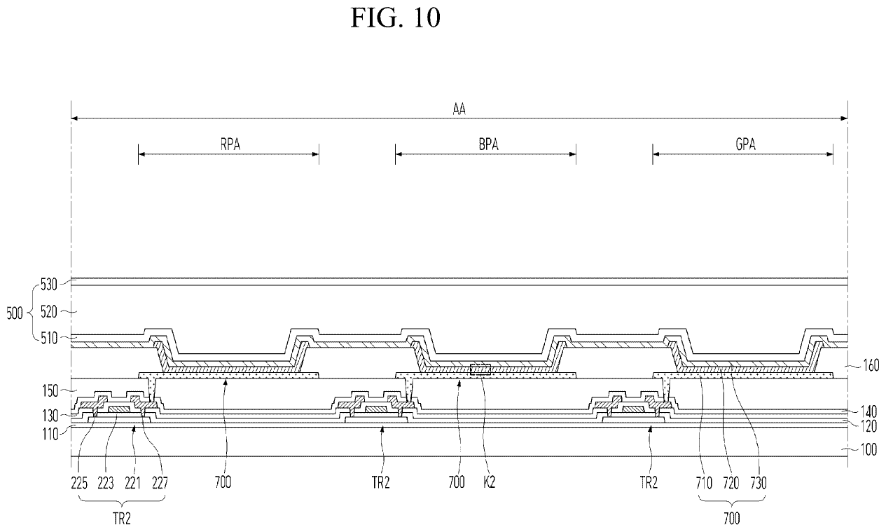

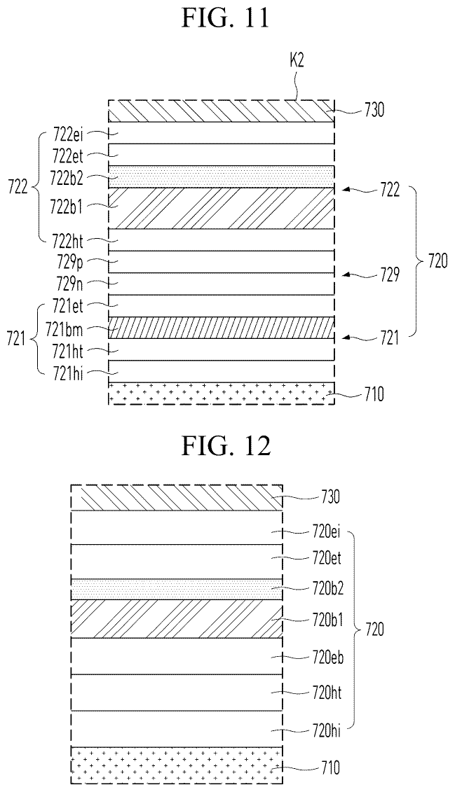

The display apparatus according to the embodiment of the present disclosure is described that the light-emitting unit 320 of each pixel area PA can emit white light. However, in the display apparatus according to another embodiment of the present invention, light emitted from the light-emitting unit 320 of each pixel area PA can display a color different from light emitted from the light-emitting unit 320 of adjacent pixel area PA. For example, in the display apparatus according to another embodiment of the present disclosure, the pixel areas can include a red pixel area RPA realizing red color, a blue pixel area BPA realizing blue color and a green pixel area GPA realizing green color, and the light-emitting unit 720 of the light-emitting device 700 in each pixel area RPA, BPA and GPA can be separated from the light-emitting unit 720 of the light-emitting device 700 in adjacent pixel area RPA, BPA and GPA, as shown in FIGS. 10 and 11, wherein FIG. 11 is an enlarged view of K2 region in FIG. 10. For example, an end of the light-emitting unit 720 in each pixel area RPA, BPA and GPA can be covered by the second electrode 730 of the corresponding pixel area RPA, BPA and GPA.

The light-emitting unit 720 of each pixel area RPA, BPA and GPA can include emission stacks 721 and 722 in which light displaying a same color are generated. For example, the light-emitting unit 720 of the light-emitting device 700 in the blue pixel area BPA can include a lower emission stack 721, a charge generation layer 729 and an upper emission stack 722, wherein the lower emission stack 721 can include a lower hole injection layer 721hi, a lower hole transport layer 721ht, a lower light-emitting layer 721bm and a lower electron transport layer 721et, wherein the upper emission stack 722 can include an upper hole transport layer 722ht, a first upper light-emitting layer 722b1, a second upper light-emitting layer 722b2, an upper electron transport layer 722et and an upper electron injection layer 722ei, wherein each of the lower light-emitting layer 721bm, the first upper light-emitting layer 722b1 and the second upper light-emitting layer 722b2 can have a single layer structure including a blue host and a blue dopant, and wherein the blue host of the second upper light-emitting layer 722b2 can have a higher triplet energy level than the blue host of the first upper light-emitting layer 722b1. The charge generation layer 729 may supply electrons or holes to adjacent emission stack 721 and 722. For example, charge generation layer 729 may have a stacked structure of a n-type charge generating layer 729n and a p-type charge generating layer 729p. Thus, in the display apparatus according to another embodiment of the present disclosure, the efficiency and life-span of the light-emitting units 720 on the pixel areas RPA, BPA and GPA displaying different colors can be improved.

In the display apparatus according to another embodiment of the present disclosure, the light-emitting unit 720 of each pixel area RPA, BPA and GPA can include a single emission stack. For example, in the display apparatus according to another embodiment of the present disclosure, the light-emitting device of each blue pixel area can include a hole injection layer 720hi, a hole transport layer 720ht, an electron blocking layer 720eb, a first blue light-emitting layer 720b1, a second blue light-emitting layer 720b2, an electron transport layer 720et, an electron injection layer 720ei and a second electrode 730, in which are sequentially stacked on a first electrode 710, wherein the first blue light-emitting layer 720b1 can include a first blue host and a first blue dopant, wherein the second blue light-emitting layer 720b2 can include a second blue host and a second blue dopant, and wherein the second blue host can have a higher triplet energy level than the first blue host, as shown in FIG. 12. Thus, in the display apparatus according to another embodiment of the present disclosure, the degree of freedom in configuring the light-emitting unit 720 disposed between the first electrode 710 and the second electrode 730 can be improved.

Although the configuration of the pixel area in FIG. 10 is explained above by taking only the light-emitting device in the blue pixel area as an example. However, it is understood that the light-emitting devices in the red pixel area RPA and the green pixel area GPA may have similar configurations. Furthermore, the above descriptions about the upper emission stack and the lower emission stack also apply to the corresponding emission stacks of the light emitting unit 720.

As a result, the display apparatus according to the embodiments of the present disclosure can comprise the light-emitting device on each pixel area, wherein the light-emitting device can include the light-emitting unit between an anode electrode and a cathode electrode, the light-emitting unit can include at least one blue emission stack, the blue emission stack can include a first light-emitting layer and a second light-emitting layer, and a host of the second light-emitting layer contacting a surface of the first light-emitting layer toward the cathode electrode can have a higher triplet energy level than a host of the first light-emitting layer. Thereby, in the display apparatus according to the embodiments of the present disclosure, deterioration of the efficiency and life-span in the light-emitting device due to the accumulation of triplet excitons can be prevented or minimized. Further, in the display apparatus according to the embodiments of the present disclosure, lower power driving is possible, and power consumption can be reduced or minimized.

What is claimed is:

1. A display apparatus comprising:
a first electrode on a pixel area of a device substrate;
an upper emission stack on the first electrode, the upper emission stack having a stacked structure of a first blue light-emitting layer and a second blue light-emitting layer;
an electron transport layer on the second blue light-emitting layer of the upper emission stack; and
a second electrode on the electron transport layer,
wherein the second blue light-emitting layer is in contact with a surface of the first blue light-emitting layer toward the electron transport layer, and
wherein a second host of the second blue light-emitting layer has a higher triplet energy level than a first host of the first blue light-emitting layer.

2. The display apparatus according to claim 1, wherein a lowest unoccupied molecular orbital (LUMO) energy level of the electron transport layer is higher than a LUMO energy level of the second blue light-emitting layer.

3. The display apparatus according to claim 1, wherein a first blue dopant of the first blue light-emitting layer has a higher triplet energy level than the first host of the first blue light-emitting layer, and
wherein a second blue dopant of the second blue light-emitting layer has a higher triplet energy level than the second host of the second blue light-emitting layer.

4. The display apparatus according to claim 3, wherein the second blue dopant includes a different material from the first blue dopant.

5. The display apparatus according to claim 3, wherein a triplet energy level of the first blue dopant is lower than a triplet energy level of the second host.

6. The display apparatus according to claim 1, wherein a thickness of the second blue light-emitting layer is smaller than a thickness of the first blue light-emitting layer.

7. The display apparatus according to claim 1, further comprising:
a lower emission stack disposed between the first electrode and the upper emission stack; and
a first charge generation layer disposed between the lower emission stack and the upper emission stack.

8. The display apparatus according to claim 7, wherein a light-emitting layer of the lower emission stack is composed of a single layer including a lower blue dopant.

9. The display apparatus according to claim 7, further comprising:
a second charge generation layer disposed between the first charge generation layer and the upper emission stack; and
an intermediate emission stack disposed between the first charge generation layer and the second charge generation layer,
wherein light emitted from the intermediate emission stack displays a different color from light emitted from the lower emissions stack and light emitted from the upper emission stack.

10. The display apparatus according to claim 9, wherein a light-emitting layer of the intermediate emission stack includes a red dopant and a green dopant.

11. A display apparatus comprising:
a first electrode on a substrate;
an intermediate charge generation layer on the first electrode;
a second electrode on the intermediate charge generation layer, the second electrode having a smaller work-function than the first electrode;
a first blue emission stack disposed between the first electrode and the intermediate charge generation layer; and
a second blue emission stack disposed between the intermediate charge generation layer and the second electrode,
wherein the second blue emission stack includes a first upper light-emitting layer and a second upper light-emitting layer contacting a surface of the first upper light-emitting layer toward the second electrode, and
wherein a host of the second upper light-emitting layer has a higher triplet energy level than a host of the first upper light-emitting layer.

12. The display apparatus according to claim 11, wherein the intermediate charge generation layer has a stacked structure of a n-type charge generating layer and a p-type charge generating layer, and
wherein the p-type charge generating layer is disposed between the n-type charge generating layer and the first upper light-emitting layer.

13. The display apparatus according to claim 11, wherein the first blue emission stack includes a first lower light-emitting layer and a second lower light-emitting layer contacting a surface of the first lower light-emitting layer toward the second electrode, and
wherein a host of the second lower light-emitting layer has a lower triplet energy level than a host of the first lower light-emitting layer.

14. The display apparatus according to claim 13, wherein a blue dopant of the first lower light-emitting layer has a higher triplet energy level than a host of the first lower light-emitting layer, and
wherein a blue dopant of the second lower light-emitting layer has a higher triplet energy level than a host of the second lower light-emitting layer.

15. The display apparatus according to claim 11, wherein a blue dopant of the first upper light-emitting layer and a blue dopant of the second upper light-emitting layer have a higher triplet energy level than the host of the second upper light-emitting layer.

16. A display apparatus comprising:
a cathode electrode and a anode electrode;
a light-emitting unit between the cathode electrode and the anode electrode,
wherein the light-emitting unit at least includes an upper emission stack which includes a first upper light-emitting layer and a second upper light-emitting layer contacting a surface of the first upper light-emitting layer toward the cathode electrode, and
wherein a second host of the second upper light-emitting layer has a higher triplet energy level than a first host of the first upper light-emitting layer.

17. The display apparatus according to claim 16, wherein the light-emitting unit further includes:
a lower emission stack between the anode electrode and the upper emission stack; and
a first charge generation layer between the lower emission stack and the upper emission stack.

18. The display apparatus according to claim 17, wherein the lower emission stack includes a lower light-emitting layer, a lower hole transport layer and an electron blocking layer between the lower light-emitting layer and the lower hole transport layer.
